(19) United States
(12) Patent Application Publication
(10) Pub. No.: US 2009/0283772 A1
(43) Pub. Date: Nov. 19, 2009

(54) PHOTO SENSITIVE UNIT AND PIXEL STRUCTURE AND LIQUID CRYSTAL DISPLAY PANEL HAVING THE SAME

(75) Inventors: An-Thung Cho, Hsinchu (TW); Wen-Jen Chiang, Hsinchu (TW); Chia-Tien Peng, Hsinchu (TW); Chrong-Jung Lin, Hsinchu City (TW); Kun-Chih Lin, Hsinchu (TW); Ya-Chin King, Taipei City (TW); Chih-Wei Chao, Hsinchu (TW); Feng-Yuan Gan, Hsinchu (TW)

Correspondence Address: J C PATENTS, 4 VENTURE, SUITE 250, IRVINE, CA, 92618, US

(73) Assignee: AU OPTRONICS CORPORATION, Hsinchu (TW)

(21) Appl. No.: 12/405,992

(22) Filed: Mar. 17, 2009

(30) Foreign Application Priority Data
May 16, 2008 (TW) 97118226

(51) Int. Cl. H01L 33/00

(52) U.S. Cl. 257/71; 257/72; 257/E33.053

(57) ABSTRACT

A pixel structure suitable for being disposed on a substrate is provided. The pixel structure includes a display unit and a photo sensitive unit. The display unit includes an active device and a pixel electrode. The active device is disposed on the substrate, and the pixel electrode is electrically connected to the active device. The photo sensitive unit includes a photocurrent readout unit, a shielding electrode, a photosensitive dielectric layer, and a transparent electrode. The shielding electrode is electrically connected to the photocurrent readout unit, and the photosensitive dielectric layer is disposed on the shielding electrode. The transparent electrode is disposed on the photosensitive dielectric layer that is interposed between the shielding electrode and the transparent electrode.

### CROSS-REFERENCE TO RELATED APPLICATION

This application claims the priority benefit of Taiwan application serial no. 97118226, filed on May 16, 2008. The entirety of the above-mentioned patent application is hereby incorporated by reference herein and made a part of this specification.

### BACKGROUND OF THE INVENTION

1. Field of the Invention

The present invention relates to a pixel structure and a display panel. More particularly, the present invention relates to a pixel structure and a liquid crystal display (LCD) panel that are equipped with a photo sensitive unit.

2. Description of Related Art

With a rapid progress in science and technology, a demand for displays is increasing along with an advancement of display technology. Conventionally, since cathode ray tubes (CRTs) are fully developed and have extraordinary display quality, the CRTs have played a dominant role in the display market for years. However, the rise of “environmental protection” awareness is against the CRTs due to the CRTs' disadvantages including high power consumption and high radiation, and the limited flattening capability of the CRTs is against the market demands for light, thin, short, small, compact, and power-saving displays. Accordingly, a compact and slim flat panel display (FPD) has gradually replaced the conventional CRT display. The most common FPD includes a plasma display panel (PDP), an LCD, a thin film transistor liquid crystal display (TFT-LCD), and so on. Here, the TFT-LCD equipped with superior properties including high image quality, good space utilization, low power consumption, and no radiation has become a mainstream display product of the market.

In the TFT-LCD, a thin film transistor (TFT) serves as an active device and can be categorized into an amorphous silicon thin film transistor (a-Si TFT) and a polysilicon thin film transistor (p-Si TFT). The p-Si TFT can be further divided into a low temperature p-Si TFT and a high temperature p-Si TFT. In most cases, polysilicon is formed by performing a low pressure chemical vapor deposition (LPCVD) process and an annealing process at 900° C. or more. Therefore, a substrate of a p-Si TFT-LCD is usually made of quartz. Nevertheless, the substrate of the p-Si TFT-LCD is often made of glass at this current stage, and a melting point of the glass substrate ranges from 500° C. to 600° C. Accordingly, a low temperature p-Si (LTPS) technique has been developed.

By applying the LTPS technique, semiconductor devices (such as the TFTs, light emitting diodes, and so on) can be formed on the glass substrate. Hence, it has been mentioned in some written references that a photo sensor and a pixel structure are simultaneously formed on the substrate through conducting the LTPS technique, such that the LCD not only can perform an image display function but also can be used for fingerprint identification.

FIG. 1 is a schematic view of a conventional photo sensor. Referring to FIG. 1, a conventional photo sensor 10 is a PIN (positive-intrinsic-negative) diode and includes a substrate 12, an active layer 14, a passivation layer 16, and a contact 18. The active layer 14 includes a P-type doped region 14a, an intrinsic region 14c, and an N-type doped region 14b. As the photo sensor 10 is pressed by a user's finger, the finger is irradiated by light emitted from a backlight source L2, and light L1 reflected by the finger illuminates the intrinsic region 14c. Energy of the reflected light L1 is absorbed by the intrinsic region 14c, and a photocurrent is then generated within the PIN diode and output through the contact 18.

However, the photo sensor 10 is irradiated by the backlight source L2 no matter whether the photo sensor 10 is pressed by the user's finger. In other words, even though the photo sensor 10 is not irradiated by the reflected light L1, the photo sensor 10 still generates the photocurrent due to the illumination of the backlight source L2 and, therefore, the photo sensor 10 becomes less photosensitive to the reflected light L1. Moreover, the strength of the backlight source L2 is usually greater than the strength of the reflected light L1. As a result, the photo sensor 10 can barely sense variations of the photocurrent caused by the reflected light L1 during the continuous illumination of the backlight source L2.

Further, in the photo sensor 10, the P-type doped region 14a, the N-type doped region 14b, and the low temperature p-Si TFT in the pixel structure are fabricated at the same time. Hence, the dopant concentration of the P-type doped region 14a and the N-type doped region 14b is very likely subject to the low temperature p-Si TFT in the pixel structure. That is to say, in a process of fabricating the conventional low temperature p-Si, considerations cannot be concurrently given to both optoelectronic characteristics of the photo sensor 10 and electronic characteristics of the low temperature p-Si TFT.

### SUMMARY OF THE INVENTION

The present invention is directed to a pixel structure having a shielding electrode to prevent light emitted by a backlight source from directly irradiating a photo sensitive unit, such that the photosensitivity of the photo sensitive unit can remain favorable.

The present invention is further directed to an LCD panel in which a pixel structure has a shielding electrode to prevent light emitted by a backlight source from directly irradiating a photo sensitive unit, such that the photosensitivity of the photo sensitive unit can remain favorable.

The present invention provides a pixel structure adapted to be disposed on a substrate. The pixel structure includes a display unit and a photo sensitive unit. The display unit includes an active device and a pixel electrode. The active device is disposed on the substrate, and the pixel electrode is electrically connected to the active device. The photo sensitive unit includes a photocurrent readout unit, a shielding electrode, a photosensitive dielectric layer, and a transparent electrode. The shielding electrode is electrically connected to the photocurrent readout unit, and the photosensitive dielectric layer is disposed on the shielding electrode. The transparent electrode is disposed on the photosensitive dielectric layer that is interposed between the shielding electrode and the transparent electrode.

In an alternative embodiment of the present invention, the display unit further includes a storage capacitor disposed below the pixel electrode and electrically connected to the active device.

In an alternative embodiment of the present invention, the active device is a first TFT, while the photocurrent readout unit is a second TFT.

In an alternative embodiment of the present invention, the first TFT includes a first p-Si TFT, while the second TFT includes a second p-Si TFT.

In an alternative embodiment of the present invention, the first p-Si TFT includes a first p-Si layer, a first gate insulation layer, a first gate electrode, a first passivation layer, a source electrode, and a drain electrode. The first p-Si layer is disposed on the substrate and includes a first source region, a first drain region, and a first channel region interposed between the first source region and the first drain region. The first gate insulation layer is disposed on the substrate to cover the first p-Si layer. The first gate electrode is disposed on the first gate insulation layer and located above the first p-Si layer. The first passivation layer is disposed on the first gate insulation layer to cover the first gate electrode. Here, the first gate insulation layer and the first passivation layer have a plurality of first contact openings exposing the first source region and the first drain region. The source electrode and the drain electrode are electrically connected to the first source region and the first drain region through the first contact openings, respectively.

In an embodiment of the present invention, a material of the source electrode, a material of the drain electrode, and a material of the shielding electrode are substantially the same.

In an embodiment of the present invention, the second p-Si TFT includes a second p-Si layer, a second gate insulation layer, a second gate electrode, and a second passivation layer. The second p-Si layer is disposed on the substrate and includes a second source region, a second drain region, and a second channel region interposed between the second source region and the second drain region. The second gate insulation layer is disposed on the substrate to cover the second p-Si layer. The second gate electrode is disposed on the second gate insulation layer and located above the second p-Si layer. The second passivation layer is disposed on the second gate insulation layer to cover the second gate electrode. Here, the second gate insulation layer and the second passivation layer have a plurality of second contact openings exposing the second source region and the second drain region, and the shielding electrode is electrically connected to the second source region or the second drain region.

In an embodiment of the present invention, the photosensitive dielectric layer includes a silicon-rich dielectric layer.

In an embodiment of the present invention, the silicon-rich dielectric layer includes a silicon-rich silicon oxide (SiOx) layer, a silicon-rich silicon nitride (SiNy) layer, a silicon-rich silicon oxynitride (SiOxNy) layer, a silicon-rich silicon oxycarbide (SiOxCz) layer, or a silicon-rich silicon carbide (SiCz) layer.

In an embodiment of the present invention, the silicon-rich dielectric layer includes a nanocrystal material layer.

In an embodiment of the present invention, the nanocrystal material layer includes a silicon-rich dielectric layer on which a laser annealing crystallization process is performed, and a plurality of nanocrystals are formed in the silicon-rich dielectric layer.

The present invention further provides an LCD panel including an active device array substrate, an opposite substrate, and a liquid crystal layer. The active device array substrate includes a plurality of scan lines, a plurality of data lines, and a plurality of pixel structures. Each of the pixel structures is electrically connected to the corresponding scan line and the corresponding data line, and each of the pixel structures includes a display unit and a photo sensitive unit. The display unit includes an active device and a pixel electrode. The active device is disposed on the substrate, and the pixel electrode is electrically connected to the active device. The photo sensitive unit includes a photocurrent readout unit, a shielding electrode, a photosensitive dielectric layer, and a transparent electrode. The shielding electrode is electrically connected to the photocurrent readout unit. The photosensitive dielectric layer is disposed on the shielding electrode. The transparent electrode is disposed on the photosensitive dielectric layer that is interposed between the shielding electrode and the transparent electrode. The opposite substrate is disposed above the active device array substrate. The liquid crystal layer is disposed between the active device array substrate and the opposite substrate.

In an embodiment of the present invention, the display unit further includes a storage capacitor disposed below the pixel electrode and electrically connected to the active device.

In an embodiment of the present invention, the active device is a first TFT, while the photocurrent readout unit is a second TFT.

In an embodiment of the present invention, the first TFT includes a first p-Si TFT, while the second TFT includes a second p-Si TFT.

In an embodiment of the present invention, the first p-Si TFT includes a first p-Si layer, a first gate insulation layer, a first gate electrode, a first passivation layer, a source electrode, and a drain electrode. The first p-Si layer is disposed on the substrate and includes a first source region, a first drain region, and a first channel region interposed between the first source region and the first drain region. The first gate insulation layer is disposed on the substrate to cover the first p-Si layer. The first gate electrode is disposed on the first gate insulation layer and located above the first p-Si layer. The first passivation layer is disposed on the first gate insulation layer to cover the first gate electrode. Here, the first gate insulation layer and the first passivation layer have a plurality of first contact openings exposing the first source region and the first drain region. The source electrode and the drain electrode are electrically connected to the first source region and the first drain region through the first contact openings, respectively.

In an embodiment of the present invention, a material of the source electrode, a material of the drain electrode, and a material of the shielding electrode are substantially the same.

In an embodiment of the present invention, the second p-Si TFT includes a second p-Si layer, a second gate insulation layer, a second gate electrode, and a second passivation layer. The second p-Si layer is disposed on the substrate and includes a second source region, a second drain region, and a second channel region interposed between the second source region and the second drain region. The second gate insulation layer is disposed on the substrate to cover the second p-Si layer. The second gate electrode is disposed on the second gate insulation layer and located above the second p-Si layer. The second passivation layer is disposed on the second gate insulation layer to cover the second gate electrode. Here, the second gate insulation layer and the second passivation layer have a plurality of second contact openings exposing the second source region and the second drain region, and the shielding electrode is electrically connected to the second source region or the second drain region.

In an embodiment of the present invention, the photosensitive dielectric layer includes a silicon-rich dielectric layer.

In an embodiment of the present invention, the silicon-rich dielectric layer includes a silicon-rich SiOx layer, a silicon-rich SiNy layer, a silicon-rich SiOxNy layer, a silicon-rich SiOxCz layer, or a silicon-rich SiCz layer.

In an embodiment of the present invention, the silicon-rich dielectric layer includes a nanocrystal material layer.

In an embodiment of the present invention, the nanocrystal material layer includes a silicon-rich dielectric layer on which a laser annealing crystallization process is performed, and a plurality of nanocrystals are formed in the silicon-rich dielectric layer.

In an embodiment of the present invention, the opposite substrate is a color filter substrate, and the color filter substrate has a plurality of patterned color filter thin films.

In an embodiment of the present invention, the patterned color filter thin films are disposed above the pixel electrodes but are not disposed above the transparent electrodes.

In an embodiment of the present invention, the patterned color filter thin films are disposed above the pixel electrodes and the transparent electrodes.

The present invention further provides a photo sensitive unit adapted to be disposed on a substrate. The photo sensitive unit includes a photocurrent readout unit, a shielding electrode, a photosensitive dielectric layer, and a transparent electrode. The shielding electrode is electrically connected to the photocurrent readout unit. The photosensitive dielectric layer has a plurality of nanocrystals disposed on the shielding electrode. The transparent electrode is disposed on the photosensitive dielectric layer that is interposed between the shielding electrode and the transparent electrode.

Since the shielding electrode is utilized for preventing the light emitted by the backlight source from directly irradiating the photo sensitive unit in the present invention, the photo sensitive unit in the pixel structure or in the LCD panel can be characterized by outstanding photosensitivity according to the present invention.

In order to make the above and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional photo sensor.

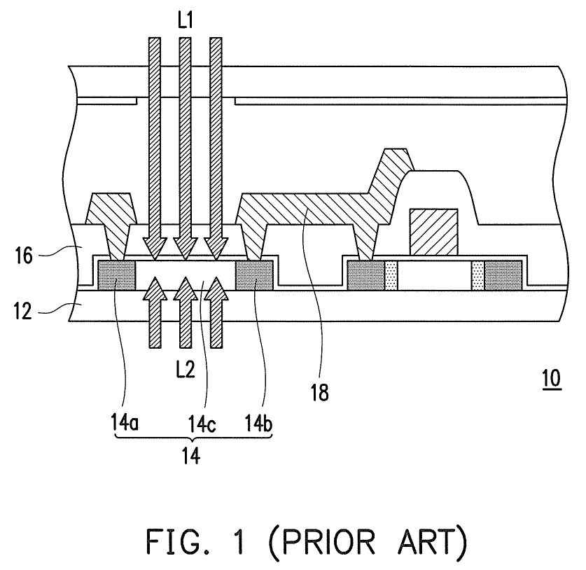

FIG. 2 is a schematic view of a pixel structure according to the present invention.

FIG. 3 is a schematic enlarged view of a display unit in the pixel structure depicted in FIG. 2.

FIG. 4 is a schematic enlarged view of a photo sensitive unit in the pixel structure depicted in FIG. 2.

FIG. 5A is a schematic top view of an LCD panel according to an embodiment of the present invention.

FIG. 5B is a cross-sectional view taken along a sectional line A-A′ depicted in FIG. 5A.

FIG. 5C is a schematic view illustrating light reflection when an LCD is covered by a user's finger.

### DESCRIPTION OF EMBODIMENTS

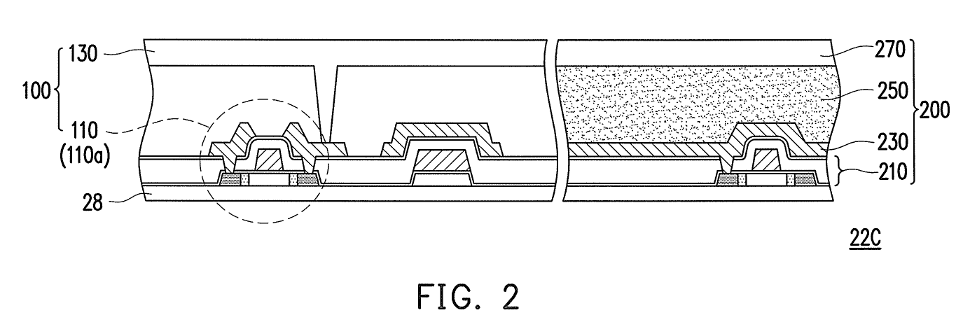

FIG. 2 is a schematic view of a pixel structure according to the present invention. Referring to FIG. 2, a pixel structure 22c is suitable for being disposed on a substrate 28 and includes a display unit 100 and a photo sensitive unit 200. The display unit 100 includes an active device 110 and a pixel electrode 130. The active device 110 is disposed on the substrate 28, and the pixel electrode 130 is electrically connected to the active device 110. The photo sensitive unit 200 includes a photocurrent readout unit 210, a shielding electrode 230, a photosensitive dielectric layer 250, and a transparent electrode 270. The shielding electrode 230 is electrically connected to the photocurrent readout unit 210, and the photosensitive dielectric layer 250 is disposed on the shielding electrode 230. The transparent electrode 270 is disposed on the photosensitive dielectric layer 250 that is interposed between the shielding electrode 230 and the transparent electrode 270.

In the present embodiment, the substrate 28 can be a glass substrate, a quartz substrate, or a plastic substrate. A material of the pixel electrode 130 and a material of the transparent electrode 270 are substantially the same. Here, the pixel electrode 130 and the transparent electrode 270 can be made of indium tin oxide (ITO), indium zinc oxide (IZO), or other transparent conductive materials. The shielding electrode 230 can be made of metals including chromium (Cr), molybdenum (Mo), titanium (Ti), tungsten (W), aluminum (Al), copper (Cu), aurum (Au), a stacked layer containing said metals, or an alloy thereof. For example, the shielding electrode 230 can be made of Ti/Al/Ti or other metallic materials. Besides, the photosensitive dielectric layer 250 can be a silicon-rich dielectric layer. In the present embodiment, the silicon-rich dielectric layer includes a super-silicon-rich dielectric layer or a silicon-rich dielectric layer on which a laser crystallization process is performed, and a plurality of nanocrystals are formed in the silicon-rich dielectric layer. Here, the silicon-rich dielectric layer is, for example, a silicon-rich silicon oxide (SiOx) layer, a silicon-rich silicon nitride (SiNy) layer, a silicon-rich silicon oxynitride (SiOxNy) layer, a silicon-rich silicon oxycarbide (SiOxCz) layer, or a silicon-rich silicon carbide (SiCz) layer, or any other appropriate material layer. Values of x, y, and z can be in the range from 0.01 to 2. Preferably, x is in a range of 0.01˜2, y is in a range of 0.01˜1.33, and z is in a range of 0.01˜1, which can be proportionally adjusted based on actual demands. The silicon-rich dielectric layer has a refraction index (n) in the range from 1.5 to 3.8. Preferably, the silicon-rich dielectric layer a refraction index in the range from 2.0 to 3.8, and most preferably in the range from 2.5 to 3.8. The photosensitive dielectric layer 250 has a plurality of high-density nanocrystals disposed therein. Here, the photosensitive dielectric layer 250 is, for example, formed by first forming the silicon-rich dielectric layer through performing a chemical vapor deposition (CVD) process. Next, the nanocrystals are formed in the photosensitive dielectric layer 250 by performing a laser crystallization process. Diameters of the nanocrystals approximately range from 0.5 nm to 200 nm, preferably from 1 nm to 50 nm. The laser used here is, for example, an excimer laser having a wavelength of 308 nm-350 nm or a CW laser having a wavelength of 500 nm-900 nm.

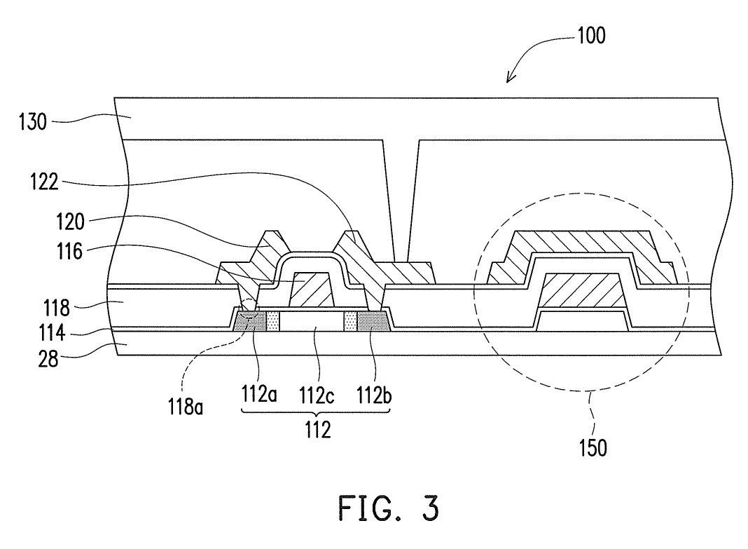

FIG. 3 is a schematic enlarged view of a display unit in the pixel structure depicted in FIG. 2. As shown in FIGS. 2 and 3, the display unit 100 in the pixel structure 22c of the present embodiment can further include a storage capacitor 150 disposed below the pixel electrode 130 and electrically connected to the active device 110. In other words, the storage capacitor 150 disclosed in the present embodiment has a storage capacitor on common electrode (Cst-on-common) structure. However, the present invention is not intended to limit the storage capacitor 150 to have the Cst-on-common structure. In other embodiments, the storage capacitor 150 can alternatively have a storage capacitor on gate electrode (Cst-on-gate) structure.

The storage capacitor 150 in the pixel structure 22c enables each pixel unit to have a temporal memory function. When the capacitance value of the storage capacitor 150 increases, the pixel memory of the written signals is improved, and the memory content can be better retained.

In detail, as indicated in FIGS. 2 and 3, the active device 110 is, for example, a first TFT. In the present embodiment, the first TFT can be a first p-Si TFT 110a including a first p-Si layer 112, a first gate insulation layer 114, a first gate electrode 116, a first passivation layer 118, a source electrode 120, and a drain electrode 122. The first p-Si layer 112 is disposed on the substrate 28 and includes a first source region 112a, a first drain region 112b, and a first channel region 112c interposed between the first source region 112a and the first drain region 112b. The first gate insulation layer 114 is disposed on the substrate 28 to cover the first p-Si layer 112. The first gate electrode 116 is disposed on the first gate insulation layer 114 and located above the first p-Si layer 112. The first passivation layer 118 is disposed on the first gate insulation layer 114 to cover the first gate electrode 116. Here, the first gate insulation layer 114 and the first passivation layer 118 have a plurality of first contact openings 118a exposing the first source region 112a and the first drain region 112b. The source electrode 120 and the drain electrode 122 are electrically connected to the first source region 112a and the first drain region 112b through the first contact openings 118a, respectively. In the present embodiment, a material of the source electrode 120 and the drain electrode 122 is often metals and is substantially equivalent to the material of the shielding electrode 230, such as Cr, Mo, Ti, W, Al, Cu, Au, a stacked layer containing said metals, or an alloy thereof. For example, the source electrode 120, the drain electrode 122, and the shielding electrode 230 can be made of Ti/Al/Ti or other metallic materials.

Note that the first p-Si TFT 110a may be a low temperature p-Si TFT or a high temperature p-Si TFT. In the present embodiment, the low temperature p-Si TFT characterized by low power consumption, great electron mobility, and effectively-integrated driving circuits is used to exemplify the present invention.

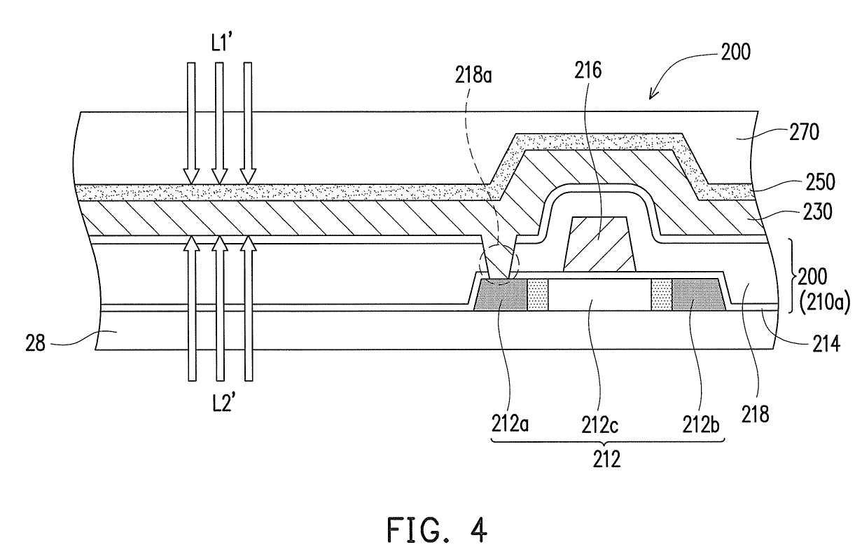

FIG. 4 is a schematic enlarged view of the photo sensitive unit in the pixel structure depicted in FIG. 2. Referring to FIG. 4, in the present embodiment, the photocurrent readout unit 210 is, for example, a second TFT. The second TFT may be a second p-Si TFT 210a. The second p-Si TFT 210a includes a second p-Si layer 212, a second gate insulation layer 214, a second gate electrode 216, and a second passivation layer 218. The second p-Si layer 212 is disposed on the substrate 28 and includes a second source region 212a, a second drain region 212b, and a second channel region 212c interposed between the second source region 212a and the second drain region 212b. The second gate insulation layer 214 is disposed on the substrate 28 to cover the second p-Si layer 212. The second gate electrode 216 is disposed on the second gate insulation layer 214 and located above the second p-Si layer 212. The second passivation layer 218 is disposed on the second gate insulation layer 214 to cover the second gate electrode 216. Here, the second gate insulation layer 214 and the second passivation layer 218 have a plurality of second contact openings 218a exposing the second source region 212a and the second drain region 212b, and the shielding electrode 230 is electrically connected to the second source region 212a or the second drain region 212b. In FIG. 4, the shielding electrode 230 is electrically connected to the second source region 212a. Note that the first passivation layer 118 and the second passivation layer 218 are, for example, made of silicon oxide, silicon nitride, or other insulation materials.

In particular, when a user's finger or a certain object is placed above the photo sensitive unit 200, light L1′ reflected by the user's finger or by the object irradiates the photosensitive dielectric layer 250. At this time, energy of the reflected light L1′ is absorbed by the photosensitive dielectric layer 250, so as to generate the photocurrent which is then output to the photocurrent readout unit 210. In comparison with the related art, the present embodiment provides the shielding electrode 230 to shield a backlight source L2′, so as to prevent the light emitted by the backlight source L2′ from directly irradiating the photosensitive dielectric layer 250. Thereby, the photo sensitive unit 200 can be much more photosensitive to the reflected light L1′.

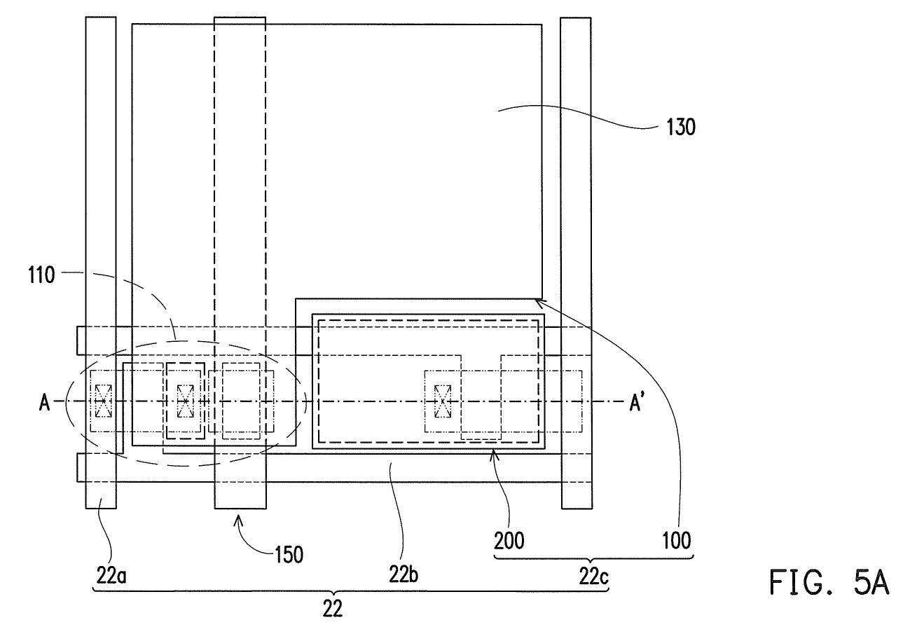

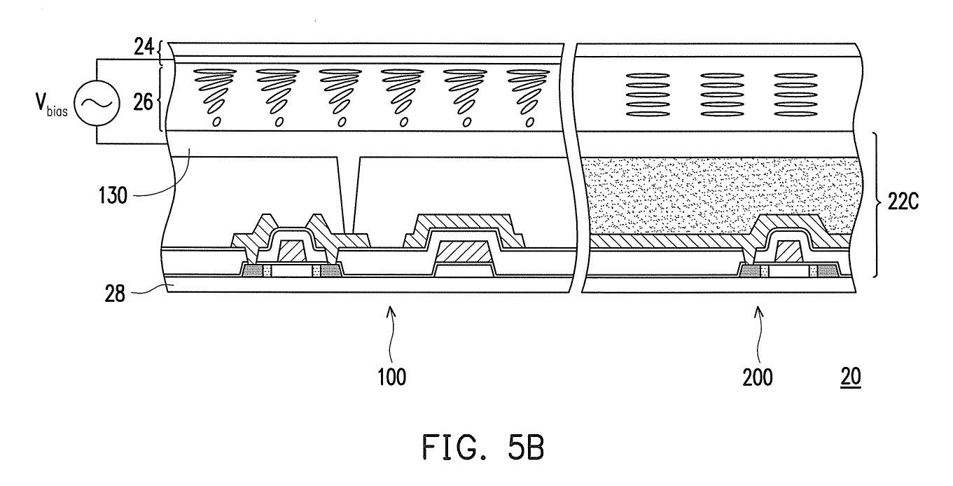

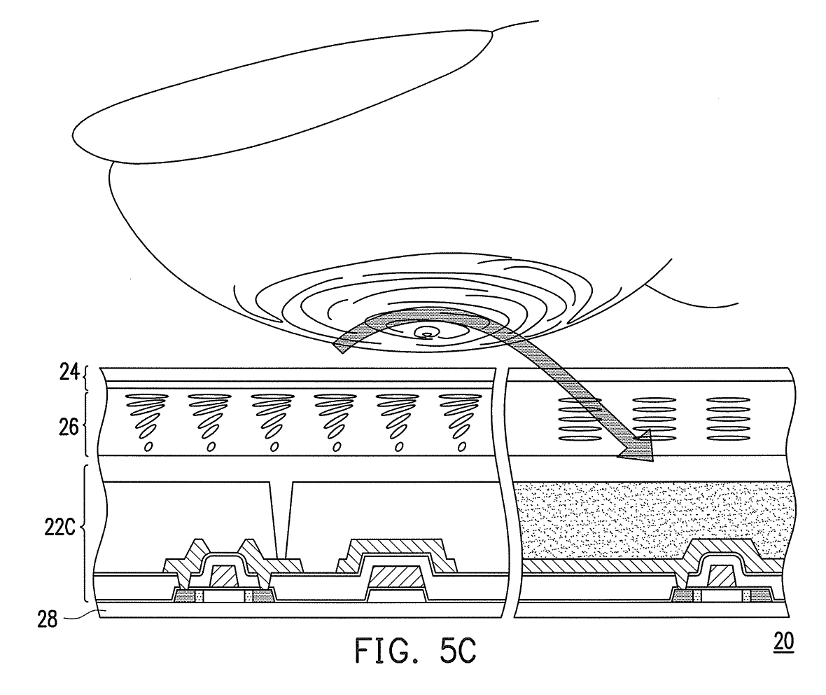

FIG. 5A is a schematic top view of an LCD panel according to an embodiment of the present invention. FIG. 5B is a cross-sectional view taken along a sectional line A-A′ depicted in FIG. SA. Referring to both FIGS. 5A and 5B, an LCD panel 20 includes an active device array substrate 22, an opposite substrate 24, and a liquid crystal layer 26. The active device array substrate 22 includes a plurality of scan lines 22a, a plurality of data lines 22b, and a plurality of pixel structures 22c. Each of the pixel structures 22c is electrically connected to the corresponding scan line 22a and the corresponding data line 22c, and each of the pixel structures 22c includes one display unit 100 and one photo sensitive unit 200. Both the display unit 100 and the photo sensitive unit 200 provided in the present embodiment are the same elements described in the previous embodiment. The opposite substrate 24 is disposed above the active device array substrate 22. The liquid crystal layer 26 is interposed between the active device array substrate 22 and the opposite substrate 24.

To allow the LCD panel 20 to perform a multi-color display function, the opposite substrate 24 may be a color filter substrate having a plurality of patterned color filter thin films. Here, the patterned color filter thin films are disposed above the pixel electrodes 130 but may not be disposed above the transparent electrodes 270 (as shown in FIG. 4). Additionally, the patterned color filter thin films may be red, green, or blue, for example.

In an alternative, the patterned color filter thin films may be disposed above the pixel electrodes 130 and the transparent electrodes 270. Therefore, when the photo sensitive unit 200 is photosensitive to a specific color light, the corresponding patterned color filter thin film can be disposed to improve the photosensitivity of the photo sensitive unit 200.

Referring to FIGS. 2 and 5B, in the present embodiment, the active device 110 and the photocurrent readout unit 210 in the LCD panel 20 are the first p-Si TFT 110a and the second p-Si TFT 210a. Here, the first p-Si TFT 110a and the second p-Si TFT 210a can be referred to as the low temperature p-Si TFT. Since the shielding electrode 230 of the photo sensitive unit 200 is utilized for preventing the light emitted by the backlight source L2′ from directly irradiating the photo sensitive unit 200 in the present embodiment, and the photo sensitive unit 200 has a relatively large photo sensing region, the LCD panel 20 acting as a fingerprint identifier/scanner is able to accomplish a comparatively satisfactory performance.

FIG. 5C is a schematic view illustrating light reflection when an LCD panel is covered by a user's finger. With reference to FIGS. 4 and 5C, when a user's finger or an object to be scanned is placed on the LCD panel 20, the liquid crystal layer 26 is driven for improving the transmittance rate, such that the reflected light L1′ penetrating the liquid crystal layer 26 is reflected to the photo sensitive unit 200. Only the user's finger covering the LCD panel 20 is schematically illustrated in FIG. 5C.

As the reflected light L1′ is reflected to the photo sensitive unit 200, the reflected light L1′ is absorbed, and the photocurrent is then generated. Thereafter, the photocurrent readout unit 210 detects photo signals and outputs the photo signals to an external integrator for converting the photocurrent to voltages. Finally, voltage signals are output and converted in an analog-to-digital manner, and appropriate image processing is performed on the voltage signals, so as to complete the fingerprint identification and the object scanning.

Specifically, when the light reflected by the user's finger to be sensed or the object to be scanned enters into the photo sensitive unit 200, the shielding electrode 230 in the bottom of the pixel structure 22c is able to prevent the light emitted by the backlight source L2′ from directly irradiating the photo sensitive unit 200. Besides, the user's finger covering the LCD panel 20 is conducive to precluding noise interference caused by an external light, so as to speed up a response to the photo signals. In comparison with the related art, the present embodiment provides the shielding electrode 230 to shield the backlight source L2′, so as to prevent the light emitted by the backlight source L2′ from directly irradiating the photosensitive dielectric layer 250. Thereby, the photo sensitive unit 200 can be much more photosensitive to the reflected light L1′. Moreover, the photosensitive dielectric layer 250 of the present invention has a better photosensitivity than the conventional a-Si layer or the conventional p-Si layer does. Accordingly, the photo sensitive unit 200 of the present embodiment is much more photosensitive to the reflected light L1′.

In summary, the pixel structure and the LCD panel provided by the present invention have at least the following advantages.

The shielding electrode placed in the bottom of the pixel structure and the user's finger covering the LCD panel are able to prevent the direct illumination of the backlight source and have a higher immunity against noise interference caused by the external light.

Given that the liquid crystal layer is biased and thereby the light transmittance rate is enhanced, the response to the photo signals can be accelerated while the LCD panel is performing the sensing function or the scanning function.

As the LCD panel of the present invention has a relatively large photosensitive region, the LCD panel acting as the fingerprint identifier/scanner is able to achieve a comparatively satisfactory performance.

The LCD panel of the present invention has an outstanding photosensitivity and low manufacturing costs.

According to several embodiments of the present invention, the LCD panel can perform a multi-color display function by means of the color filter substrate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pixel structure, suitable for being disposed on a substrate, the pixel structure comprising:
a display unit, comprising:
an active device, disposed on the substrate;
a pixel electrode, electrically connected to the active device;
a photo sensitive unit, comprising:
a photocurrent readout unit;
a shielding electrode, electrically connected to the photocurrent readout unit;
a photosensitive dielectric layer, disposed on the shielding electrode; and
a transparent electrode, disposed on the photosensitive dielectric layer,
wherein the photosensitive dielectric layer is interposed between the shielding electrode and the transparent electrode.

2. The pixel structure as claimed in claim 1, wherein the display unit further comprises a storage capacitor disposed below the pixel electrode and electrically connected to the active device.

3. The pixel structure as claimed in claim 1, wherein the active device is a first thin film transistor, while the photocurrent readout unit is a second thin film transistor.

4. The pixel structure as claimed in claim 3, wherein the first thin film transistor comprises a first polysilicon thin film transistor, while the second thin film transistor comprises a second polysilicon thin film transistor.

5. The pixel structure as claimed in claim 4, wherein the first polysilicon thin film transistor comprises:
a first polysilicon layer, disposed on the substrate and comprising a first source region, a first drain region, and a first channel region interposed between the first source region and the first drain region;
a first gate insulation layer, disposed on the substrate to cover the first polysilicon layer;
a first gate electrode, disposed on the first gate insulation layer and located above the first polysilicon layer;
a first passivation layer, disposed on the first gate insulation layer to cover the first gate electrode, wherein the first gate insulation layer and the first passivation layer have a plurality of first contact openings exposing the first source region and the first drain region;
a source electrode; and
a drain electrode, wherein the source electrode and the drain electrode are electrically connected to the first source region and the first drain region through the first contact openings, respectively.

6. The pixel structure as claimed in claim 5, wherein a material of the source electrode, a material of the drain electrode, and a material of the shielding electrode are substantially the same.

7. The pixel structure as claimed in claim 4, wherein the second polysilicon thin film transistor comprises:
a second polysilicon layer, disposed on the substrate and comprising a second source region, a second drain region, and a second channel region interposed between the second source region and the second drain region;
a second gate insulation layer, disposed on the substrate to cover the second polysilicon layer;
a second gate electrode, disposed on the second gate insulation layer and located above the second polysilicon layer; and
a second passivation layer, disposed on the second gate insulation layer to cover the second gate electrode, wherein the second gate insulation layer and the second passivation layer have a plurality of second contact openings exposing the second source region and the second drain region, and the shielding electrode is electrically connected to the second source region or the second drain region.

8. The pixel structure as claimed in claim 1, wherein the photosensitive dielectric layer comprises a silicon-rich dielectric layer.

9. The pixel structure as claimed in claim 8, wherein the silicon-rich dielectric layer comprises a silicon-rich silicon oxide layer, a silicon-rich silicon nitride layer, a silicon-rich silicon oxynitride layer, a silicon-rich silicon oxycarbide layer, or a silicon-rich silicon carbide layer.

10. The pixel structure as claimed in claim 8, wherein the silicon-rich dielectric layer comprises a nanocrystal material layer.

11. The pixel structure as claimed in claim 10, wherein the nanocrystal material layer comprises a silicon-rich dielectric layer on which a laser annealing crystallization process is performed, and a plurality of nanocrystals are formed in the silicon-rich dielectric layer.

12. The pixel structure as claimed in claim 8, wherein the silicon-rich dielectric layer has a refraction index in the range from 1.5 to 3.8.

13. A liquid crystal display panel, comprising:
an active device array substrate, comprising:
a plurality of scan lines;
a plurality of data lines;
a plurality of pixel structures, wherein each of the pixel structures is electrically connected to the corresponding scan line and the corresponding data line, and each of the pixel structures comprises:
a display unit, comprising:
an active device, disposed on the substrate;
a pixel electrode, electrically connected to the active device;
a photo sensitive unit, comprising:
a photocurrent readout unit;
a shielding electrode, electrically connected to the photocurrent readout unit;
a photosensitive dielectric layer, disposed on the shielding electrode; and
a transparent electrode, disposed on the photosensitive dielectric layer, wherein the photosensitive dielectric layer is interposed between the shielding electrode and the transparent electrode;
an opposite substrate, disposed above the active device array substrate; and
a liquid crystal layer, sandwiched between the active device array substrate and the opposite substrate.

14. The liquid crystal display panel as claimed in claim 13, wherein the display unit further comprises a storage capacitor disposed below the pixel electrode and electrically connected to the active device.

15. The liquid crystal display panel as claimed in claim 13, wherein the active device is a first thin film transistor, while the photocurrent readout unit is a second thin film transistor.

16. The liquid crystal display panel as claimed in claim 15, wherein the first thin film transistor comprises a first polysilicon thin film transistor, while the second thin film transistor comprises a second polysilicon thin film transistor.

17. The liquid crystal display panel as claimed in claim 16, wherein the first polysilicon thin film transistor comprises:
a first polysilicon layer, disposed on the substrate and comprising a first source region, a first drain region, and a first channel region interposed between the first source region and the first drain region;
a first gate insulation layer, disposed on the substrate to cover the first polysilicon layer;
a first gate electrode, disposed on the first gate insulation layer and located above the first polysilicon layer;
a first passivation layer, disposed on the first gate insulation layer to cover the first gate electrode, wherein the first gate insulation layer and the first passivation layer have a plurality of first contact openings exposing the first source region and the first drain region;
a source electrode; and
a drain electrode, wherein the source electrode and the drain electrode are electrically connected to the first source region and the first drain region through the first contact openings, respectively.

18. The liquid crystal display panel as claimed in claim 17, wherein a material of the source electrode, a material of the drain electrode, and a material of the shielding electrode are substantially the same.

19. The liquid crystal display panel as claimed in claim 16, wherein the second polysilicon thin film transistor comprises:
a second polysilicon layer, disposed on the substrate and comprising a second source region, a second drain region, and a second channel region interposed between the second source region and the second drain region;
a second gate insulation layer, disposed on the substrate to cover the second polysilicon layer;
a second gate electrode, disposed on the second gate insulation layer and located above the second polysilicon layer; and
a second passivation layer, disposed on the second gate insulation layer to cover the second gate electrode, wherein the second gate insulation layer and the second passivation layer have a plurality of second contact openings exposing the second source region and the second drain region, and the shielding electrode is electrically connected to the second source region or the second drain region.

20. The liquid crystal display panel as claimed in claim 13, wherein the photosensitive dielectric layer comprises a silicon-rich dielectric layer.

21. The liquid crystal display panel as claimed in claim 20, wherein the silicon-rich dielectric layer comprises a silicon-rich silicon oxide layer, a silicon-rich silicon nitride layer, a silicon-rich silicon oxynitride layer, a silicon-rich silicon oxycarbide layer, or a silicon-rich silicon carbide layer.

22. The liquid crystal display panel as claimed in claim 20, wherein the silicon-rich dielectric layer comprises a nanocrystal material layer.

23. The liquid crystal display panel as claimed in claim 22, wherein the nanocrystal material layer comprises a silicon-rich dielectric layer on which a laser annealing crystallization process is performed, and a plurality of nanocrystals are formed in the silicon-rich dielectric layer.

24. The liquid crystal display panel as claimed in claim 20, wherein the silicon-rich dielectric layer has a refraction index in the range from 1.5 to 3.8.

25. The liquid crystal display panel as claimed in claim 13, wherein the opposite substrate is a color filter substrate, and the color filter substrate has a plurality of patterned color filter thin films.

26. The liquid crystal display panel as claimed in claim 25, wherein the patterned color filter thin films are disposed above the pixel electrodes but are not disposed above the transparent electrodes.

27. A photo sensitive unit, suitable for being disposed on a substrate, the photo sensitive unit comprising:
a photocurrent readout unit;
a shielding electrode, electrically connected to the photocurrent readout unit;
a photosensitive dielectric layer, having a plurality of nanocrystals disposed on the shielding electrode; and
a transparent electrode, disposed on the photosensitive dielectric layer, wherein the photosensitive dielectric layer is interposed between the shielding electrode and the transparent electrode.
